(19) United States
(12) Patent Application Publication
(10) Pub. No.: US 2025/0088154 A1
(43) Pub. Date: Mar. 13, 2025

(54) LINEAR POWER SOURCE CIRCUIT

(71) Applicant: ROHM CO., LTD., Kyoto-shi (JP)

(72) Inventor: Takashige MIYASHITA, Kyoto-shi (JP)

(21) Appl. No.: 18/828,108

(22) Filed: Sep. 9, 2024

(30) Foreign Application Priority Data
Sep. 12, 2023 (JP) 2023-147677

(51) Int. Cl. H03F 3/45; H03F 3/21; H03F 3/42

(52) U.S. Cl. CPC H03F 3/45179; H03F 3/21; H03F 3/423; H03F 2203/45046

(57) ABSTRACT

A linear power source circuit includes: an input unit to which an input signal is input and which outputs a first current signal; a current-voltage convertor which converts the first current signal into a first voltage signal; a voltage-current convertor configured to convert the first voltage signal into a second current signal; and an output unit configured to generate an output voltage signal from the second current signal by a first current mirror unit, a second current mirror unit, and a third current mirror unit, and configured to output the output voltage signal to an output terminal. The input unit and the current-voltage convertor constitute a current feedback type operational amplifier.

### CROSS-REFERENCE TO RELATED APPLICATIONS

The present invention claims priority under 35 U.S.C. § 119 to Japanese Patent Application No. 2023-147677, filed on Sep. 12, 2023, the entire contents of which are incorporated herein by reference.

### TECHNICAL FIELD

The present disclosure relates to a linear power source circuit.

### BACKGROUND

As a related art of the present disclosure, a VCM driver for driving a voice coil motor (VCM) is known.

### BRIEF DESCRIPTION OF THE DRAWINGS

FIG. 1 is a block diagram of a linear power source circuit according to an embodiment.

FIG. 2A is a diagram illustrating a configuration example of a first current mirror circuit used in the embodiment.

FIG. 2B is a diagram illustrating a configuration example of a second current mirror circuit used in the embodiment.

FIG. 3 is a circuit diagram of a VCM driver using the linear power source circuit according to the embodiment.

FIG. 4 is a diagram illustrating a relationship between an input voltage Vi and output voltages VA, VB of the VCM driver using the linear power source circuit according to the embodiment.

FIG. 5 is an enlarged view of a region Vin FIG. 4.

FIG. 6 is a diagram illustrating an amplification factor G(VA) of a first output voltage VA of the VCM driver using the linear power source circuit according to the embodiment.

FIG. 7 is a diagram illustrating an operation waveform of each part with respect to the input voltage Vi of the VCM driver using the linear power source circuit according to the embodiment.

FIG. 8 is a circuit diagram of a VCM driver using a linear power source circuit of a comparative example.

FIG. 9 is a diagram illustrating a relationship between an input voltage Vi and output voltages VA, VB of the VCM driver using the linear power source circuit of the comparative example.

FIG. 10 is an enlarged view of a region X in FIG. 9.

FIG. 11 is a diagram illustrating an amplification factor G(VA) of a first output voltage VA of the VCM driver using the linear power source circuit of the comparative example.

FIG. 12 is a diagram illustrating an operation waveform of each part with respect to the input voltage Vi of the VCM driver using the linear power source circuit of the comparative example.

FIG. 13 is a diagram illustrating an operation waveform of each part with respect to the input voltage Vi of the VCM driver using a through current prevention circuit provided in the linear power source circuit of the comparative example.

### DETAILED DESCRIPTION

An embodiment will be described below with reference to the drawings. Note that the embodiment described below represent a comprehensive or specific example. Numerical values, shapes, materials, components, and installation positions and connection forms of the components shown in the following embodiment are merely examples, and are not limited to the present disclosure. In addition, among the components in the following embodiment, components that are not described in the independent claim, which represents the highest concept, will be described as optional components. Moreover, the dimensional ratios of the drawings are exaggerated for the convenience of description, and may be different from actual ratios in some cases.

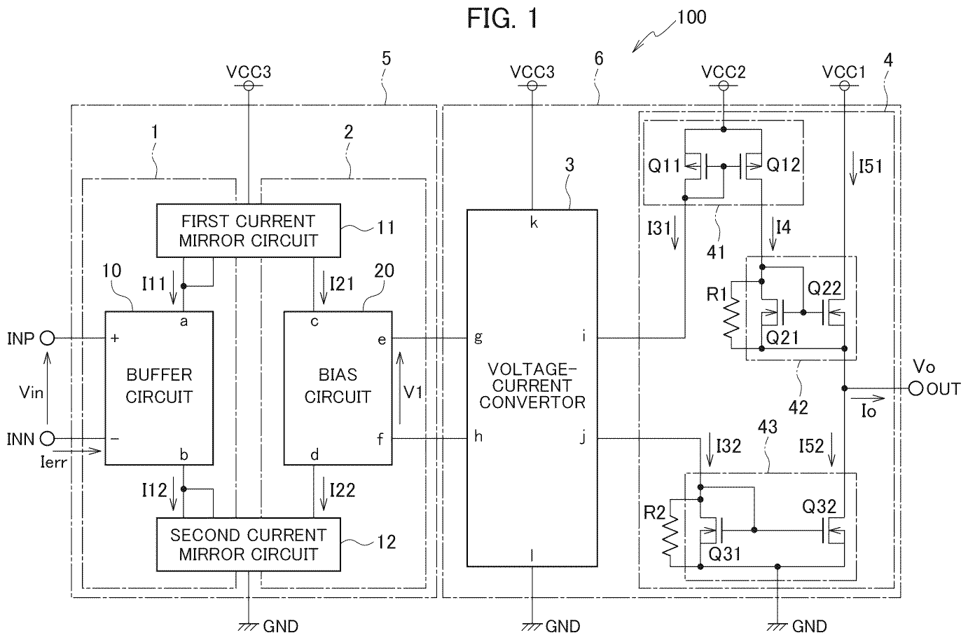

FIG. 1 is a block diagram of a linear power source circuit 100 according to an embodiment. The linear power source circuit 100 is configured to be applicable to a power amplifier of a VCM driver. The linear power source circuit 100 includes a positive input terminal INP and a negative input terminal INN as input terminals, an input unit 1, a current-voltage convertor 2, a voltage-current convertor 3, an output unit 4, and an output terminal OUT.

The input unit 1 receives, as input signals, an input voltage Vin input between the positive input terminal INP and the negative input terminal INN and a feedback current Ierr input to the negative input terminal INN, and generates first current signals I11, I12 corresponding to the input signals. The current-voltage convertor 2 converts mirror currents I21, I22 generated by a first current mirror circuit 11 and a second current mirror circuit 12 as mirror currents of the first current signals I11, I12 into a first voltage signal V1. The value of the first voltage signal V1 changes depending on the balance between the mirror current I21 and the mirror current I22. The voltage-current convertor 3 converts the first voltage signal V1 into second current signals I31, I32 and outputs the converted signals. The output unit 4 generates an output voltage signal Vo from the second current signals I31, I32 by means of the first current mirror unit 41, the second current mirror unit 42, and the third current mirror unit 43, and outputs the output voltage signal Vo to the output terminal OUT. A first DC power source VCC1 and a second DC power source VCC2 are connected to the output unit 4. A third DC power source VCC3 is connected to the input unit 1, the current-voltage convertor 2, and the voltage-current convertor 3.

The input unit 1 includes a buffer circuit 10. The buffer circuit 10 is formed of, for example, a single ended push-pull (SEPP) circuit. In the buffer circuit 10, the input impedance of the positive input terminal + is high, while the input impedance of the negative input terminal − is low. That is, as a feature of the current feedback type operational amplifier, since the negative input terminal − corresponds to an output terminal of the buffer circuit 10, the input impedance of the negative input terminal − is low. The positive input terminal INP is connected to the positive input terminal + of the buffer circuit 10, and the negative input terminal INN is connected to the negative input terminal − of the buffer circuit 10.

The current-voltage convertor 2 includes a bias circuit 20. The bias circuit 20 is connected to the buffer circuit 10 via the first current mirror circuit 11 and the second current mirror circuit 12.

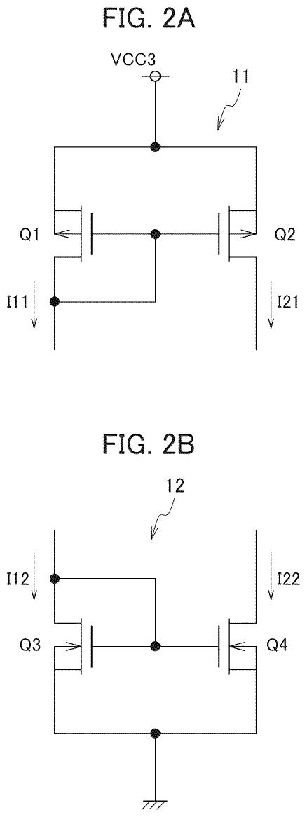

For example, as illustrated in FIG. 2A, the first current mirror circuit 11 includes a first preceding transistor Q1 and a second preceding transistor Q2. The first preceding transistor Q1 and the second preceding transistor Q2 are each formed of a P-channel type MOSFET (metal-oxide-semiconductor field-effect transistor), for example. The control electrode (e.g., a gate) of the first preceding transistor Q1 is connected to the first main electrode (e.g., a drain) of the first preceding transistor Q1 and the control electrode (e.g., a gate) of the second preceding transistor Q2. The second main electrodes (e.g., sources) of the first preceding transistor Q1 and the second preceding transistor Q2 are connected to each other to form a power source terminal connected to the third DC power source VCC3. The first main electrode (e.g., a drain) of the first preceding transistor Q1 is a reference current terminal through which a reference current (a first current signal I11) flows. The first main electrode (e.g., a drain) of the second preceding transistor Q2 is a mirror current terminal through which the mirror current I21 flows. By changing the size of the second preceding transistor Q2 relative to the first preceding transistor Q1, the ratio (a mirror ratio) between the first current signal I11 that is a reference current and the mirror current I21 can be adjusted. For example, if the first preceding transistor Q1 and the second preceding transistor Q2 are of the same size, the mirror ratio is 1, that is, the first current signal I11=the mirror current I21 is obtained.

For example, as illustrated in FIG. 2B, the second current mirror circuit 12 includes a third preceding transistor Q3 and a fourth preceding transistor Q4. The third preceding transistor Q3 and the fourth preceding transistor Q4 are each formed of an N-channel type MOSFET, for example. The control electrode (e.g., a gate) of the third preceding transistor Q3 is connected to the first main electrode (e.g., a drain) of the third preceding transistor Q3 and the control electrode (e.g., a gate) of the fourth preceding transistor Q4. The second main electrodes (e.g., sources) of the third preceding transistor Q3 and the fourth preceding transistor Q4 are connected to each other to form a power source terminal connected to the ground. The first main electrode (e.g., a drain) of the third preceding transistor Q3 is a reference current terminal through which a reference current (a first current signal I12) flows. The first main electrode (e.g., a drain) of the fourth preceding transistor Q4 is a mirror current terminal through which the mirror current I22 flows. By changing the size of the fourth preceding transistor Q4 relative to the third preceding transistor Q3, the ratio (a mirror ratio) between the first current signal I12 that is a reference current and the mirror current I22 can be adjusted. For example, if the third preceding transistor Q3 and the fourth preceding transistor Q4 are of the same size, the mirror ratio is 1, that is, the first current signal I12=the mirror current I22 is obtained. In addition, when a feedback current Ierr flowing into the negative input terminal INN is 0, the first current signal I11=I12 is obtained. When the feedback current Ierr flowing into the negative input terminal INN is not 0, the first current signal I11+Ierr=I12 is obtained.

The configurations of the first current mirror circuit 11 and the second current mirror circuit 12 are not limited to those described above. Since the current mirror circuit is a well-known existing technology, a designer can select an appropriate configuration.

In the first current mirror circuit 11, a DC voltage of the third DC power source VCC3 is supplied to the power source terminal, the reference current terminal is connected to a first terminal a of the buffer circuit 10, and the mirror current terminal is connected to a first terminal c of the bias circuit 20. In the second current mirror circuit 12, the power source terminal is connected to the ground, the reference current terminal is connected to a second terminal b of the buffer circuit 10, and the mirror current terminal connected to a second terminal d of the bias circuit 20. The input unit 1 includes the first preceding transistor Q1 of the first current mirror circuit 11 and the third preceding transistor Q3 of the second current mirror circuit 12. The current-voltage convertor 2 includes the second preceding transistor Q2 of the first current mirror circuit 11 and the fourth preceding transistor Q4 of the second current mirror circuit 12.

The input unit 1 and the current-voltage convertor 2 constitute a current feedback type operational amplifier 5.

The buffer circuit 10 generates the first current signal I11 at the first terminal a and the first current signal I12 at the second terminal b according to input signals input to the positive input terminal + and the negative input terminal −, for example, the input voltage Vin and the feedback current Ierr. The mirror current I21 having a predetermined mirror ratio to the first current signal I11 is generated by the first current mirror circuit 11 and inputted to the first terminal c of the bias circuit 20. The mirror current I22 having a predetermined mirror ratio to the first current signal I12 is generated by the second current mirror circuit 12 and output from the second terminal d of the bias circuit 20. The bias circuit 20 outputs the first voltage signal V1 corresponding to the mirror currents I21, I22 between a third terminal e and a fourth terminal f. The first voltage signal V1 is input between a first terminal g and a second terminal h of the voltage-current convertor 3.

The voltage-current convertor 3 converts the first voltage signal V1 input between the first terminal g and the second terminal h into the second current signals I31, I32, and outputs the converted signals from the third terminal i and the fourth terminal j to the output unit 4. The second current signals I31, I32 include a positive-side second current signal I31 flowing from the output unit 4 into the third terminal i of the voltage-current convertor 3, and a negative-side second current signal I32 flowing from the fourth terminal j of the voltage-current convertor 3 to the output unit 4. In the voltage-current convertor 3, a DC voltage of the third DC power source VCC3, which is the same as that of the input unit 1 and the current-voltage convertor 2, is supplied to a power source terminal k. In addition, the ground terminal 1 of the voltage-current convertor 3 is connected to the ground. In order to suppress oscillation, the voltage-current convertor 3 may be provided with a phase compensation circuit for compensating the phase of the second current signals I31, I32 with respect to the phase of the first voltage signal V1.

The voltage-current convertor 3 and the output unit 4 constitute a class-AB amplifier 6. The bias circuit 20 supplies to the voltage-current convertor 3, the first voltage signal V1 obtained by superimposing a voltage obtained by performing current-voltage conversion of the mirror currents I21, I22 of the first current signals I11, I12 corresponding to the input signals Vin, Ierr and a bias voltage of the class-AB amplifier 6.

The current feedback type operational amplifier 5 is configured to increase a transimpedance by means of the bias circuit 20. The transimpedance of the current feedback type operational amplifier corresponds to an open loop gain in a voltage feedback type operational amplifier. By increasing the transimpedance of the current feedback type operational amplifier 5, the responsiveness can be improved, and the linearity of the input and output characteristics can be improved by reducing a gain error. The means for increasing the transimpedance of the current feedback type operational amplifier 5 is not limited to the bias circuit 20.

The output unit 4 includes the first current mirror unit 41, the second current mirror unit 42, and the third current mirror unit 43.

The first current mirror unit 41 includes a first transistor Q11 and a second transistor Q12. The first transistor Q11 and the second transistor Q12 are each formed of a P-channel type MOSFET which is a P-channel type MOS transistor. The control electrode (gate) of the first transistor Q11 is connected to the first main electrode (drain) of the first transistor Q11 and the control electrode (gate) of the second transistor Q12. The second main electrodes (sources) of the first transistor Q11 and the second transistor Q12 are connected to the second DC power source VCC2. The first main electrode (drain) of the first transistor Q11 is connected to the third terminal i of the voltage-current convertor 3, and the positive-side second current signal I31 that is a reference current flows therethrough. A third current signal I4 that is a mirror current of the positive-side second current signal I31 flows through the first main electrode (drain) of the second transistor Q12.

By changing the size of the second transistor Q12 relative to the first transistor Q11, the ratio (a mirror ratio) between the positive-side second current signal I31 that is a reference current and the third current signal I4 that is a mirror current can be adjusted. For example, if the first transistor Q11 and the second transistor Q12 are of the same size, the mirror ratio of the first current mirror 41 is 1, that is, the positive-side second current signal I31 and the third current signal I4 become equal. In the embodiment, the mirror ratio of the first current mirror 41 is 1.

The second current mirror 42 includes a third transistor Q21 and a fourth transistor Q22. The third transistor Q21 and the fourth transistor Q22 are each formed of an N-channel type power MOSFET which is an N-channel type MOS transistor. The first main electrode (drain) of the third transistor Q21 is connected to the first main electrode (drain) of the second transistor Q12 through which the third current signal I4 flows. The control electrode (gate) of the third transistor Q21 is connected to the first main electrode (drain) of the third transistor Q21 and the control electrode (gate) of the fourth transistor Q22. The first main electrode (drain) of the fourth transistor Q22 is connected to the first DC power source VCC1, and a positive-side fourth current signal I51 that is a mirror current of the third current signal I4 flows therethrough. The second main electrode (source) of the fourth transistor Q22 is connected to the second main electrode (source) of the third transistor Q21.

The third current mirror unit 43 includes a fifth transistor Q31 and a sixth transistor Q32. The fifth transistor Q31 and the sixth transistor Q32 are each formed of an N-channel type power MOSFET which is an N-channel type MOS transistor. The first main electrode (drain) of the fifth transistor Q31 is connected to the fourth terminal j of the voltage-current convertor 3, and the negative-side second current signal I32 flows therethrough. The control electrode (gate) of the fifth transistor Q31 is connected to the first main electrode (drain) of the fifth transistor Q31 and the control electrode (gate) of the sixth transistor Q32. The first main electrode (drain) of the sixth transistor Q32 is connected to the second main electrode (source) of the fourth transistor Q22. The second main electrode (source) of the fifth transistor Q31 and the second main electrode (source) of the sixth transistor Q32 are connected to the ground. The negative-side fourth current signal I52 that is a mirror current of the negative-side second current signal I32 flows through the first main electrode (drain) of the sixth transistor Q32.

The series circuit in which the fourth transistor Q22 and the sixth transistor Q32 which are formed of an N-channel type power MOSFET are connected in series is an output stage, and the output terminal OUT is connected to the connection point between the fourth transistor Q22 and the sixth transistor Q32. The fourth transistor Q22 is a high-side transistor of the output stage, and the sixth transistor Q32 is a low-side transistor of the output stage. In addition, the third transistor Q21 and the fifth transistor Q31 are class-AB bias circuits of the output stage of the series circuit of the fourth transistor Q22 and the sixth transistor Q32.

In a configuration in which a voltage feedback type operational amplifier is used in a linear power source circuit, if both the high-side transistor and the low-side transistor of the output stage are formed of an N-channel type power MOSFET, an appropriate class-AB amplifier operation cannot be achieved in view of a circuit. In addition, in order to prevent the output from oscillating, it is necessary to keep the open-loop gain of the voltage feedback type operational amplifier as low as possible, which deteriorates the linearity of the input and output characteristics and the responsiveness.

In contrast, in the linear power source circuit 100 according to the embodiment, the current feedback type operational amplifier 5 is configured of the input unit 1 and the current-voltage convertor 2, which increases the transimpedance, thereby improving the responsiveness and oscillation stability. Further, the class-AB amplifier 6 is configured of the voltage-current convertor 3 and the output unit 4, which makes it possible to drive simultaneously the fourth transistor Q22 and the sixth transistor Q32 of the output stage, which are formed of an N-channel type power MOSFET. Accordingly, an idling current can be set appropriately, and thus no through current flows through the output stage.

A first resistor R1 for reducing an idling current may be connected in parallel to the third transistor Q21 of the second current mirror unit 42. A second resistor R2 for reducing an idling current may be connected in parallel to the fifth transistor Q31 of the third current mirror unit 43.

In the embodiment, the mirror ratio of the first current mirror unit 41 is set to 1, and the first current mirror unit 41 outputs the third current signal I4 having the same magnitude as the positive-side second current signal I31. The third current signal I4 having the same magnitude as the positive-side second current signal I31 is input to the second current mirror unit 42 as a reference current. The negative-side second current signal I32 is input to the third current mirror unit 43 as a reference current. When the mirror ratio between the second current mirror unit 42 and the third current mirror unit 43 is set to any equal value greater than 1, an amplification factor of I51/I31=I52/I32>1 can be obtained. For example, when the mirror ratio between the second current mirror unit 42 and the third current mirror unit 43 is set to 1000, I51/I31=I52/I32=1000 can be obtained. Since a maximum output current Io is about 3 [A], when the mirror ratio is set to 1000, the maximum current values of I31, I32, and I4 are about 3 [mA] which is 1/1000 of the output current Io. The method of setting the mirror ratio between the first current mirror unit 41, the second current mirror unit 42, and the third current mirror unit 43 is not limited to the above description, and the mirror rate may be set appropriately according to the purpose. In the output current signal Io, Io=I4+I51−I52 is obtained.

Using the above configuration, in the output unit 4, the positive-side second current signal I31 is converted into the gate-source voltage of the fourth transistor Q22, the negative-side second current signal I32 is converted into the gate-source voltage of the sixth transistor Q32, and the output voltage signal Vo is output to the output terminal OUT. That is, the output unit 4 performs current-voltage conversion of the positive-side second current signal I31 and the negative-side second current signal I32 into the output voltage signal Vo.

The first DC power source VCC1 is set to a DC voltage of, for example, +12 V. The second DC power source VCC2 is set to a voltage value higher than the first DC power source VCC1, for example, a DC voltage of +12 V+5.25 V=+17.25 V. The third DC power source VCC3 is set to a voltage value lower than the first DC power source VCC1 and the second DC power source VCC2, for example, a DC voltage of 5.25 V. The input unit 1, the current-voltage convertor 2, and the voltage-current convertor 3, which are connected to the third DC power source VCC3, can be configured of 5 V system electronic circuit elements.

In the linear power source circuit 100, since the input unit 1, the current-voltage convertor 2, and the voltage-current convertor 3 can be configured of 5 V system electronic circuit elements, the area can be reduced when the linear power source circuit 100 is configured of a single IC (integrated circuit) chip. Further, since the linear power source circuit 100 according to the embodiment has a simple circuit configuration, a low current consumption can be achieved. Furthermore, in the linear power source circuit 100 according to the embodiment, an idling current can be reduced by adding the first resistor R1 in parallel to the second current mirror unit 42 of the output unit 4 and adding the second resistor R2 in parallel to the third current mirror unit 43.

In the linear power source circuit 100, since the fourth transistor Q22 as the high-side transistor and the sixth transistor Q32 as the low-side transistor are configured of the same element, that is, formed of an N-channel type power MOSFET in the embodiment, the responsiveness can be improved.

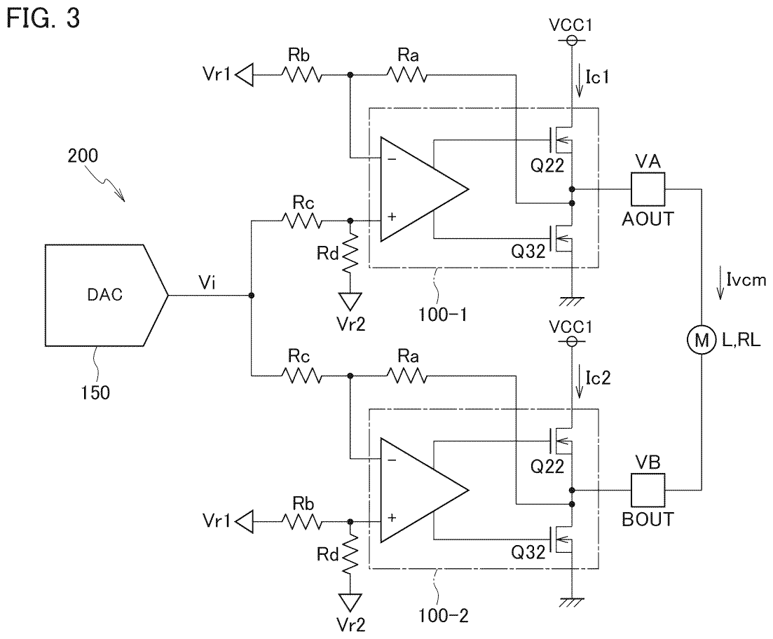

Next, an operation of the linear power source circuit 100 will be described with reference to FIGS. 3 to 7 using an example as a case in which the linear power source circuit 100 according to the embodiment is used as a power amplifier of a VCM (voice coil motor) driver 200 for driving the voice coil motor.

As illustrated in FIG. 3, the VCM driver 200 includes a first linear power source circuit 100-1 and a second linear power source circuit 100-2 having the same configuration as the linear power source circuit 100. The fourth transistor Q22 as a high-side transistor and the sixth transistor Q32 as a low-side transistor are formed of an N-channel type power transistor.

An input voltage Vi as a signal source from a digital-analog converter (DAC) 150 is input to the positive input terminal of the first linear power source circuit 100-1 via a resistor Rc, and is input to the negative input terminal of the second linear power source circuit 100-2 via a resistor Rc. In the first linear power source circuit 100-1, a first reference voltage Vr1 is input to the negative input terminal via a resistor Rb, a second reference voltage Vr2 is input to the positive input terminal via a resistor Rd, the output terminal is connected to the negative input terminal via a resistor Ra, and the output terminal is connected to a first output terminal AOUT. In the second linear power source circuit 100-2, the first reference voltage Vr1 is input to the positive input terminal via a resistor Rb, the second reference voltage Vr2 is input to the positive input terminal via a resistor Rd, the output terminal is connected to the negative input terminal via a resistor Ra, and the output terminal is connected to a second output terminal BOUT. The first reference voltage Vr1 is a voltage for biasing the midpoint of the input voltage Vi. The second reference voltage Vr2 is a voltage for biasing the midpoint of the first output voltage VA of the first output terminal AOUT and the second output voltage VB of the second output terminal BOUT.

A voice coil motor M is connected between the first output terminal AOUT and the second output terminal BOUT. Here, Lis an inductance component of the voice coil motor M, and RL is a resistance component of the voice coil motor M.

The ideal values of the first output voltage VA and the second output voltage VB of the VCM driver 200 configured as above are expressed by the following equations (1) and (2).

$$VA = Vr 2 + G ( Vi - Vr 1 ) \qquad ( 1 )$$

$$VB = Vr 2 - G ( Vi - Vr 1 ) \qquad ( 2 )$$

Here, G is an amplification factor, which is set by the resistance values of the resistors Ra, Rb, Rc, and Rd. In general, when Rb=Rc=Rx and Ra=Rd=Ry are defined, an amplification factor G=Ry/Rx is set.

Next, the simulation results of the relationship between the input voltage Vi and the output voltages VA and VB of the VCM driver 200 configured as described above will be described with reference to FIGS. 4 to 7. Here, the first linear power source circuit 100-1 and the second linear power source circuit 100-2 are both set to an amplification factor G=12. In addition, the first DC power source VCC1 is set to +12 V, the first reference voltage Vr1 is set to +0.75 V, which is the midpoint voltage value of the input voltage Vi, and the second reference voltage Vr2 is set to +6 V, which is the midpoint voltage value of the first DC power source VCC1. In addition, the inductance L of the voice coil motor M is set to 1 mH and the resistance RL is set to 8Ω. Further, Rb=Rc=16 kΩ and Ra=Rd=192 kΩ are defined, and thus the amplification factor G=192/16=12 is set.

Under these conditions, the ideal values of the first output voltage VA and the second output voltage VB are expressed by the following equations (3) and (4).

$$VA = 6 + 12 \times ( Vi - 0.75 ) = - 3 + 12 Vi \qquad ( 3 )$$

$$VB = 6 - 12 \times ( Vi - 0.75 ) = 15 - 12 Vi \qquad ( 4 )$$

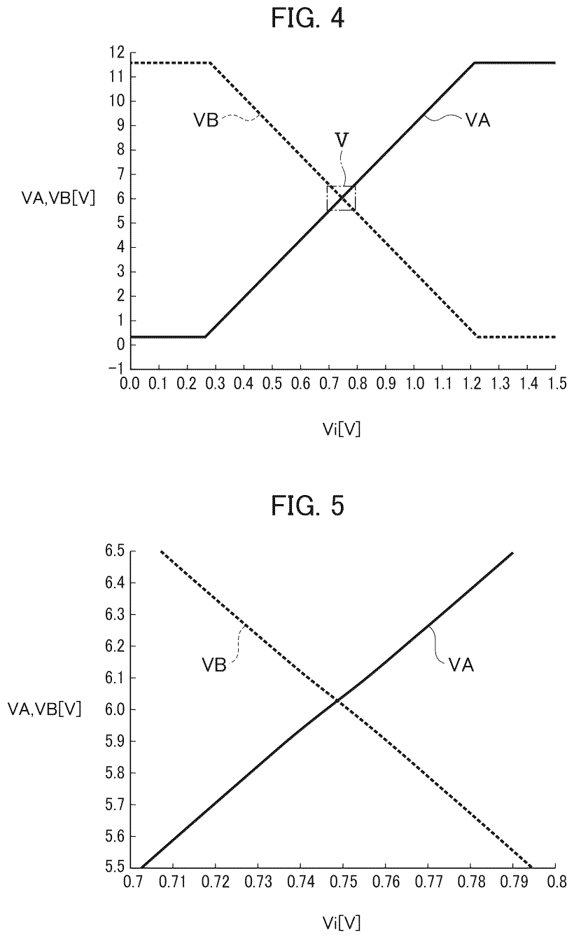

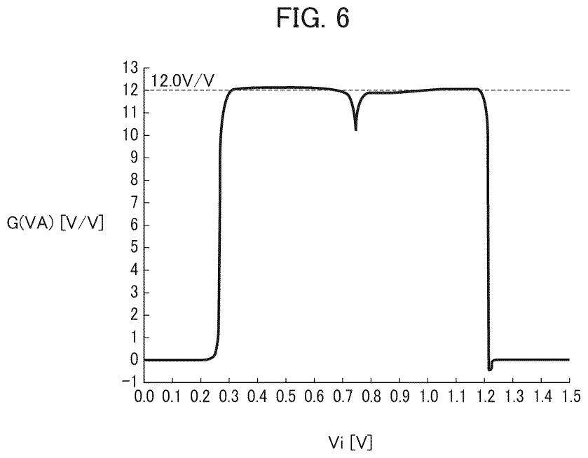

FIG. 4 is a diagram plotting a relationship between the input voltage Vi and the first output voltage VA and the second output voltage VB when the input voltage Vi from the DAC 150 is scanned from 0 V to 1.5 V under such conditions, and FIG. 5 illustrates an enlarged region V near the center of FIG. 4. Further, FIG. 6 is a diagram plotting a relationship between the input voltage Vi and the amplification factor G(VA) of the first output voltage VA when the input voltage Vi from the DAC 150 is scanned from 0 V to 1.5 V in order to further clarify the linearity of the input voltage Vi and the first output voltage VA. The amplification factor G(VA) of the first output voltage VA is expressed by the following equation (5) from the equation (1).

$$G ( VA ) = dVA / dVi = ( VA - Vr 2 ) / ( Vi - Vr 1 ) \qquad ( 5 )$$

The amplification factor G(VB) of the second output voltage VB is expressed by the following equation (6) from the equation (2).

$$G ( VB ) = dVB / dVi = ( Vr 2 - VB ) / ( Vi - Vr 1 ) \qquad ( 6 )$$

As can be seen from FIGS. 4 and 5, in the range of the input voltage Vi from 0.3 V to 1.2 V, the linearity of the first output voltage VA and the second output voltage VB with respect to the input voltage Vi is good. Further, as can be seen from FIG. 6, in the range of the input voltage Vi from 0.3 V to 1.2 V, the amplification factor G(VA) almost coincides with the set amplification factor G=12 except that the amplification factor G(VA) slightly deteriorates in the vicinity where the input voltage Vi becomes the first reference voltage Vr1=0.75 V, and thus the gain error is small. The small gain error confirms that the linearity of the input voltage Vi and the first output voltage VA is good.

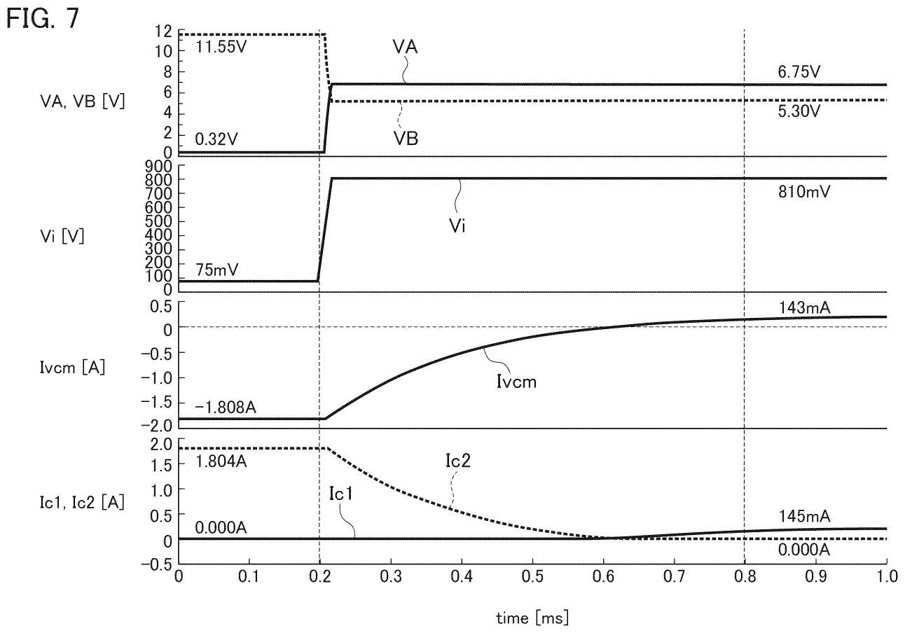

FIG. 7 illustrates a voltage or a current waveform of each part when the input voltage Vi is changed stepwise from 75 mV to 810 mV at time 0.2 ms. Here, Ivem is a current flowing through the voice coil motor M, Ic1 is a current flowing through the high-side transistor Q22 of the first linear power source circuit 100-1, and Ic2 is a current flowing through the high-side transistor Q22 of the second linear power source circuit 100-2.

When the input voltage Vi changes from 75 mV to 810 mV, the first output voltage VA changes from the initial value of 0.32 V to 6.75 V, the second output voltage VB changes from the initial value of 11.55 V to 5.30 V, and Ic1, Ic2, and Ivcm change accordingly. When the input voltage Vi=810 mV, the amplification factor G(VA)=12.5 is obtained from the first output voltage VA=6.75 V and the equation (5), and the amplification factor G(VB)=11.6 is obtained from the second output voltage VB=5.30 V and the equation (6). Thus, in the embodiment, it can be seen that the gain error of the amplification factor G(VA) and the amplification factor G(VB) is small with respect to the set amplification factor G=12.

In addition, when a linear power source circuit using a voltage feedback type operational amplifier as the power amplifier of the VCM driver is employed, a through current described below occurs in the high-side transistor Q22 and the low-side transistor Q32 of the output stage at the timing when the input voltage Vi changes stepwise. In contrast, as in the embodiment, when the linear power source circuit 100 using the current feedback type operational amplifier 5 is employed as the power amplifier of the VCM driver 200, as can be seen from the graph lines of Ic1 and Ic2 in FIG. 7, a through current generated in the high-side transistor Q22 and the low-side transistor Q32 of the output stage can be prevented.

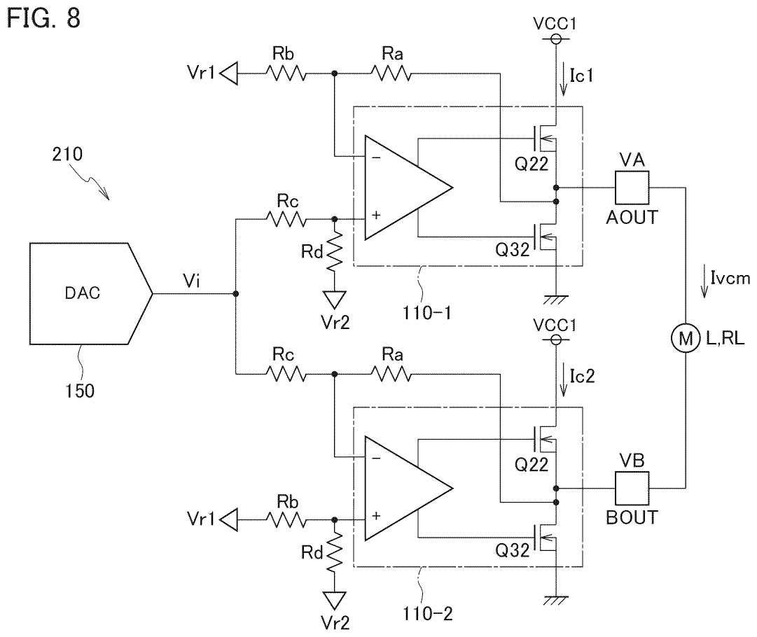

Next, for the purpose of comparison with the embodiment, an operation which a linear power source circuit 110 of a comparative example will be described with reference to FIGS. 8 to 13 using an example as a case in which the linear power source circuit 110 of the comparative example is used in a VCM driver 210. The linear power source circuit 100 of the embodiment is configured using the current feedback type operational amplifier 5; however, the linear power source circuit 110 of the comparative example differs in that the input unit is configured using a voltage feedback type operational amplifier of a differential pair.

As illustrated in FIG. 8, in the comparative example, the VCM driver 210 includes a first linear power source circuit 110-1 and a second linear power source circuit 110-2 each of which is the linear power source circuit 110 using a voltage feedback type operational amplifier. Except for the above configuration, the VCM driver 210 has the same configurations as those of the VCM driver 200 of the embodiment illustrated in FIG. 3. Further, as in the embodiment, Rb=Rc=16 kΩ and Ra=Rd=192 kΩ are defined, and thus the amplification factor G=12 is set.

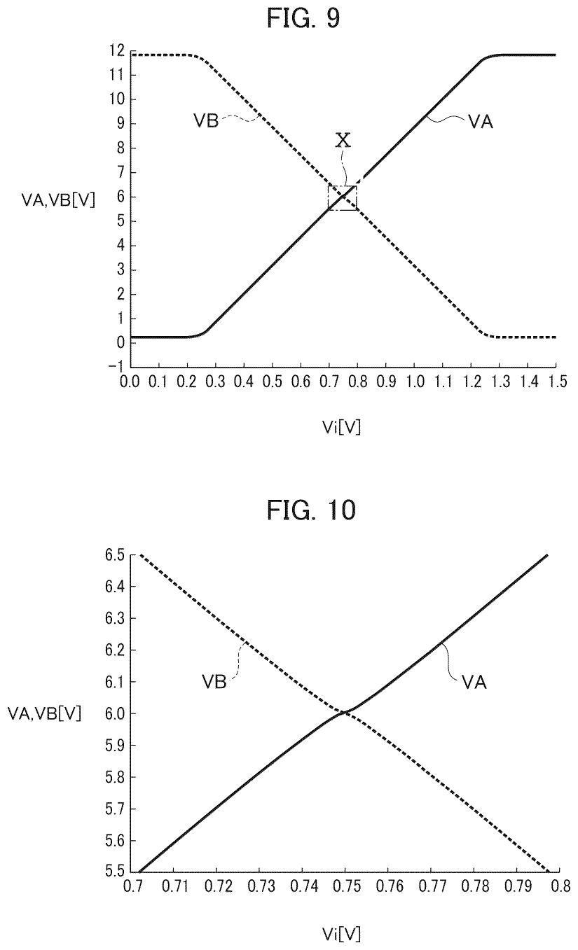

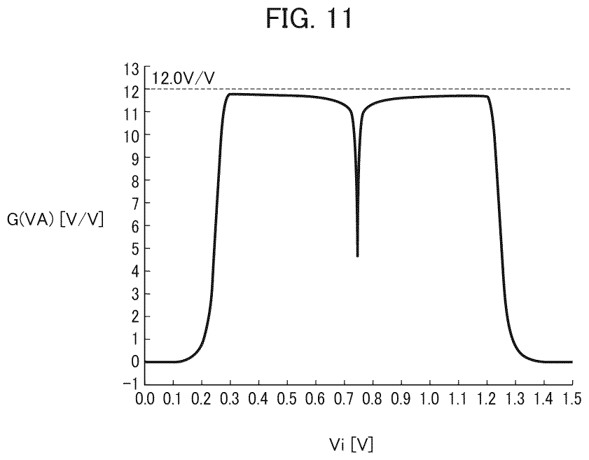

FIG. 9 is a diagram plotting a relationship between the input voltage Vi and the first output voltage VA and the second output voltage VB when the input voltage Vi from the DAC 150 is scanned from 0 V to 1.5 V in the VCM driver 210 of the comparative example, and FIG. 10 illustrates an enlarged region X near the center of FIG. 9. FIG. 11 is a diagram plotting a relationship between the input voltage Vi and the amplification factor G(VA) of the first output voltage VA when the input voltage Vi from the DAC 150 is scanned from 0 to 1.5 V.

As can be seen from FIGS. 9 and 10, in the range of the input voltage Vi from 0.3 V to 1.2 V, the linearity of the first output voltage VA and the second output voltage VB with respect to the input voltage Vi deteriorates in the vicinity of the first reference voltage Vr1=0.75 V that is the bias voltage of the input voltage Vi. Further, as can be seen from FIG. 11, in the range of the input voltage Vi from 0.3 V to 1.2 V, the amplification factor G(VA) not only deteriorates greatly in the vicinity where the input voltage Vi becomes the first reference voltage Vr1=0.75 V, but also the overall accuracy with respect to the set amplification factor G=12 is poor, and thus the gain error is large. The large gain error confirms that the linearity of the input voltage Vi and the first output voltage VA is not good.

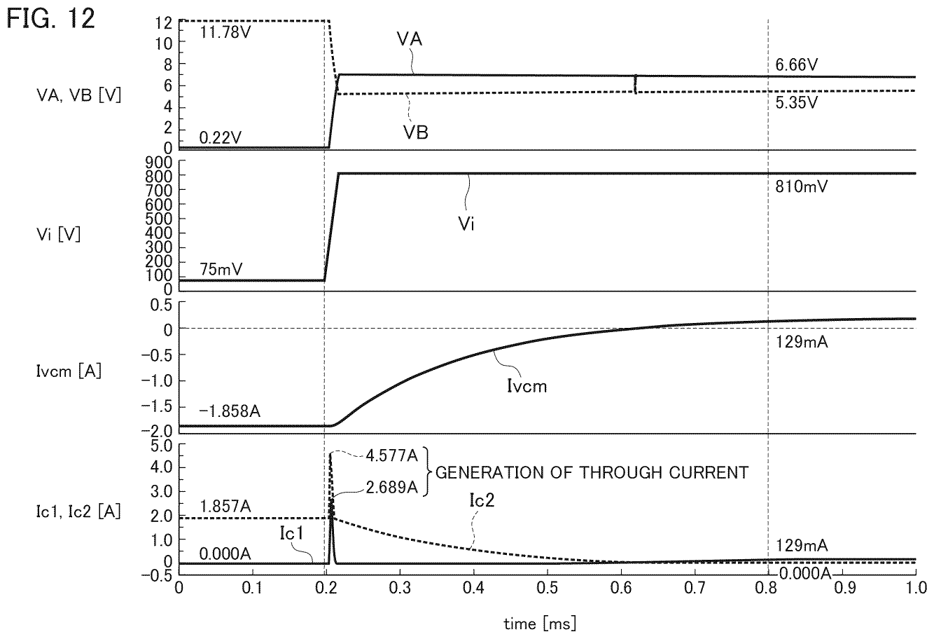

FIG. 12 illustrates a voltage or a current waveform of each part when the input voltage Vi is changed stepwise from 75 mV to 810 mV at time 0.2 ms in the VCM driver 210 of the comparative example.

When the input voltage Vi changes from 75 mV to 810 mV, the first output voltage VA changes from the initial value 0.22 V to 6.66 V, the second output voltage VB changes from the initial value 11.78 V to 5.35 V, and Ic1, Ic2, and Ivem change accordingly. When the input voltage Vi is 810 mV, the amplification factor G(VA)=11.0 is obtained from the first output voltage VA=6.66 V and the equation (5), and the amplification factor G(VB)=10.8 is obtained from the second output voltage VB=5.35 V and the equation (6). Thus, as compared with the embodiment, in the comparative example, it can be seen that the gain error of the amplification factor G(VA) and the amplification factor G(VB) is large with respect to the set amplification factor G=12.

In addition, in the VCM driver 210 of the comparative example, the linear power source circuit 110 using the voltage feedback type operational amplifier as the power amplifier is employed. For this reason, as illustrated in the graph lines of Ic1 and Ic2 in FIG. 12, a through current is generated when the high-side transistor Q22 and the low-side transistor Q32 are switched ON simultaneously at the timing in which the input voltage Vi changes stepwise.

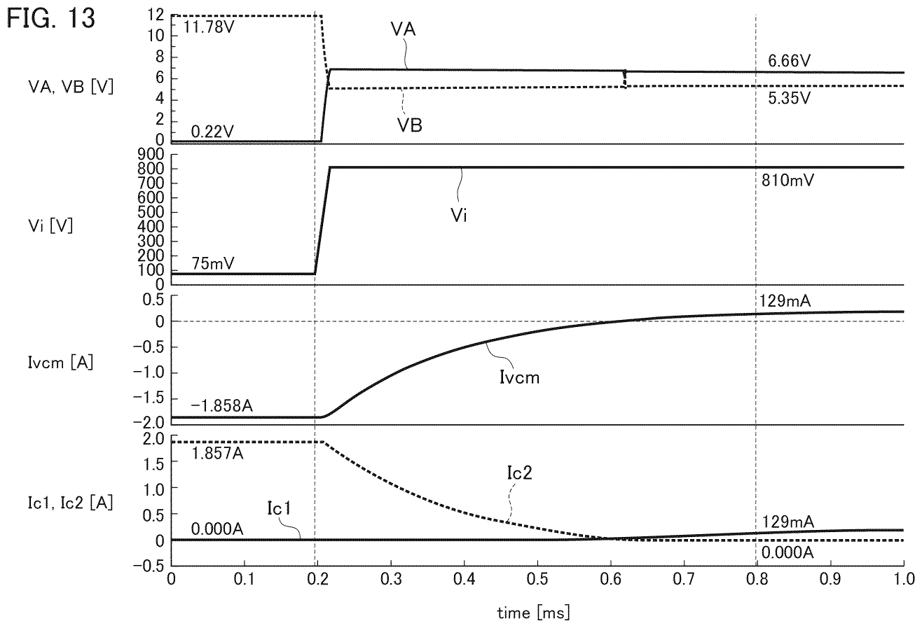

In the linear power source circuit 110 using the voltage feedback type operational amplifier, in order to prevent the generation of a through current, it is necessary to provide a through current prevention circuit inside the linear power source circuit 110. FIG. 13 illustrates a voltage or a current waveform of each part when the input voltage Vi is changed stepwise from 75 mV to 810 mV at time 0.2 ms in the VCM driver 210 of the comparative example using the linear power source circuit 110 with the through current prevention circuit provided therein.

Thus, by providing the through current prevention circuit inside the linear power source circuit 110, as illustrated in the graph lines of Ic1 and Ic2 in FIG. 13, a through current can be prevented, and the other operations are the same as those in FIG. 12. However, if the linear power source circuit 110 with the through current prevention circuit provided therein is configured of a single IC (integrated circuit) chip, which complicates the internal circuit configuration, thereby increasing the area and the current consumption.

As compared with the VCM driver 210 of the comparative example configured by the linear power source circuit 110 using a voltage feedback type operational amplifier, the VCM driver 200 configured by the linear power source circuit 100 using the current feedback type operational amplifier 5 according to the embodiment has the following improvements. That is, the VCM driver 200 configured by the linear power source circuit 100 has good linearity of input and output characteristics and a small gain error. Further, since a through current is not generated in the VCM driver 200 configured by the linear power source circuit 100, it is not necessary to provide a through current prevention circuit in the linear power source circuit 100, thereby reducing the area of the linear power source circuit 100.

### (Supplementary Note 1)

The linear power source circuit 100 includes: the input unit 1 to which the input signal Vin is input and configured to output the first current signals I11, I12; the current-voltage convertor 2 configured to convert the first current signals I11, I12 into the first voltage signal V1; the voltage-current convertor 3 configured to convert the first voltage signal V1 into the second current signals I31, I32; and the output unit 4 configured to generate the output voltage signal Vo from the second current signals I31, I32 by the first current mirror unit 41, the second current mirror unit 42, and the third current mirror unit 43, and configured to output the output voltage signal Vo to the output terminal OUT. The input unit 1 and the current-voltage convertor 2 constitute the current feedback type operational amplifier 5.

The configuration as described in Supplementary Note 1 makes it possible to realize a linear power source circuit having good linearity of the input and output characteristics and a small gain error.

### (Supplementary Note 2)

In the linear power source circuit 100 according to Supplementary Note 1, the second current signals I31, I32 include the positive-side second current signal I31 flowing into the voltage-current convertor 3 and the negative-side second current signal I32 flowing from the voltage-current convertor 3. Further, the output unit 4 has: the first current mirror unit 41 having the first transistor Q11 through which the positive-side second current signal I31 flows and the second transistor Q12 through which the third current signal I4 which is a mirror current of the positive-side second current signal I31 flows; the second current mirror unit 42 having the third transistor Q21 through which the third current signal I4 flows and the fourth transistor Q22 through which the mirror current I51 of the third current signal I4 flows; the third current mirror unit 43 having the fifth transistor Q31 through which the negative-side second current signal I32 flows and the sixth transistor Q32 through which the mirror current I52 of the negative-side second current signal I32 flows; and the series circuit in which the fourth transistor Q22 and the sixth transistor Q32 are connected in series.

### (Supplementary Note 3)

In the linear power source circuit 100 according to Supplementary Note 2, the first end of the series circuit is connected to the first DC power source VCC1, and the second end of the series circuit is connected to the ground potential GND. Further, each of the third transistor Q21, the fourth transistor Q22, the fifth transistor Q31, and the sixth transistor Q32 is an N-channel type MOS transistor. Further, the output voltage signal Vo is output to the output terminal OUT connected to the connection point between the fourth transistor Q22 and the sixth transistor Q32.

### (Supplementary Note 4)

In the linear power source circuit 100 according to Supplementary Note 3, each of the first transistor Q11 and the second transistor Q12 is a P-channel type MOS transistors.

### (Supplementary Note 5)

In the linear power source circuit 100 according to Supplementary Note 3 or 4, the second DC power source VCC2 for driving the first current mirror unit 41 has a voltage value higher than that of the first DC power source VCC1.

### (Supplementary Note 6)

In the linear power source circuit 100 according to Supplementary Note 5, the third DC power source VCC3 for driving the input unit 1, the current-voltage convertor 2, and the voltage-current convertor 3 has a voltage value smaller than that of the first DC power source VCC1 and the second DC power source VCC2.

### (Supplementary Note 7)

In the linear power source circuit 100 according to any one of Supplementary Notes 2 to 6, the output unit 4 further includes the first resistor R1 connected in parallel to the second current mirror unit 42, and the second resistor R2 connected in parallel to the third current mirror unit 43.

### (Supplementary Note 8)

In the linear power source circuit 100 according to any one of Supplementary Notes 1 to 7, the input unit 1 includes the input terminals INP and INN to which the input signal Vin is input and the buffer circuit 10 connected to the input terminals INP and INN, and outputs the first current signals I11, I12 from the buffer circuit 10 to the current-voltage convertor 2.

### (Supplementary Note 9)

In the linear power source circuit 100 according to Supplementary Note 8, the buffer circuit 10 is formed of the single ended push-pull (SEPP) circuit.

### (Supplementary Note 10)

In the linear power source circuit 100 according to any one of Supplementary Notes 1 to 9, the voltage-current convertor 3 and the output unit 4 constitute the class-AB amplifier 6.

### (Supplementary Note 11)

In the linear power source circuit 100 according to Supplementary Note 10, the current-voltage convertor 2 includes the bias circuit 20 of the class AB amplifier 6.

The present disclosure has been described above in detail. However, it is obvious to a person skilled in the art that the present disclosure is not limited to the embodiment described above. One or more elements of one embodiment may be combined with one or more elements of another embodiment. Variations and modifications may be made to the present disclosure without departing from the sprit and scope of the present disclosure defined by the claims. Thus, the present disclosure described above is for illustrative purpose and is not intended to limit the present disclosure.

1. A linear power source circuit, comprising:
an input unit to which an input signal is input and configured to output a first current signal;
a current-voltage convertor configured to convert the first current signal into a first voltage signal;
a voltage-current convertor configured to convert the first voltage signal into a second current signal; and
an output unit configured to generate an output voltage signal from the second current signal by a first current mirror unit, a second current mirror unit, and a third current mirror unit, and configured to output the output voltage signal to an output terminal, wherein
the input unit and the current-voltage convertor constitute a current feedback type operational amplifier.

2. The linear power source circuit according to claim 1, wherein
the second current signal includes a positive-side second current signal flowing into the voltage-current convertor and a negative-side second current signal flowing from the voltage-current convertor, and
the output unit comprises:
the first current mirror unit having a first transistor through which the positive-side second current signal flows and a second transistor through which a third current signal which is a mirror current of the positive-side second current signal flows;
the second current mirror unit having a third transistor through which the third current signal flows and a fourth transistor through which a mirror current of the third current signal flows;
the third current mirror unit having a fifth transistor through which the negative-side second current signal flows and a sixth transistor through which a mirror current of the negative-side second current signal flows; and
a series circuit in which the fourth transistor and the sixth transistor are connected in series.

3. The linear power source circuit according to claim 2, wherein
a first end of the series circuit is connected to a first DC power source, and a second end of the series circuit is connected to a ground potential,
each of the third transistor, the fourth transistor, the fifth transistor, and the sixth transistor is an N-channel type MOS transistor, and
the output voltage signal is output to the output terminal connected to a connection point between the fourth transistor and the sixth transistor.

4. The linear power source circuit according to claim 3, wherein each of the first transistor and the second transistor is a P-channel type MOS transistors.

5. The linear power source circuit according to claim 3, wherein a second DC power source for driving the first current mirror unit has a voltage value higher than that of the first DC power source.

6. The linear power source circuit according to claim 5, wherein a third DC power source for driving the input unit, the current-voltage convertor, and the voltage-current convertor has a voltage value smaller than that of the first DC power source and the second DC power source.

7. The linear power source circuit according to claim 2, wherein the output unit further includes a first resistor connected in parallel to the second current mirror unit, and a second resistor connected in parallel to the third current mirror unit.

8. The linear power source circuit according to claim 1, wherein the input unit includes an input terminal to which the input signal is input and a buffer circuit connected to the input terminal, and outputs the first current signal from the buffer circuit to the current-voltage convertor.

9. The linear power source circuit according to claim 8, wherein the buffer circuit is formed of a single ended push-pull circuit.

10. The linear power source circuit according to claim 1, wherein the voltage-current convertor and the output unit constitute a class-AB amplifier.

11. The linear power source circuit according to claim 10, wherein the current-voltage convertor includes a bias circuit of the class AB amplifier.
